(19) United States
(12) Patent Application Publication
(10) Pub. No.: US 2024/0421156 A1
(43) Pub. Date: Dec. 19, 2024

(54) STACKED TRANSISTOR STRUCTURES WITH HYBRID GATE PITCH

(71) Applicant: International Business Machines Corporation, Armonk, NY (US)

(72) Inventors: Ruilong Xie, Niskayuna, NY (US); Biswanath Senapati, Mechanicville, NY (US); Albert M. Chu, Nashua, NH (US); Brent A. Anderson, Jericho, VT (US)

(21) Appl. No.: 18/334,817

(22) Filed: Jun. 14, 2023

(51) Int. Cl. H01L 27/092; H01L 21/8238; H01L 29/06; H01L 29/423; H01L 29/66; H01L 29/775; H01L 29/786

(52) U.S. Cl. CPC H01L 27/0922; H01L 21/823871; H01L 29/0673; H01L 29/42392; H01L 29/66469; H01L 29/66545; H01L 29/775; H01L 29/78696

(57) ABSTRACT

A semiconductor structure includes a first set of transistors in a first level, the first set of transistors having a first gate pitch and a first cell height, and a second set of transistors in a second level, the second set of transistors having a second gate pitch and a second cell height. The second level is vertically stacked over the first level, the first gate pitch is different than the second gate pitch, and the first cell height is different than the second cell height.

### BACKGROUND

The present application relates to semiconductors, and more specifically, to techniques for forming semiconductor structures. Semiconductors and integrated circuit chips have become ubiquitous within many products, particularly as they continue to decrease in cost and size. There is a continued desire to reduce the size of structural features and/or to provide a greater amount of structural features for a given chip size. Miniaturization, in general, allows for increased performance at lower power levels and lower cost. Present technology is at or approaching atomic level scaling of certain micro-devices such as logic gates, field-effect transistors (FETs), and capacitors.

### SUMMARY

Embodiments of the invention provide techniques for forming stacked transistor structures with hybrid gate pitch.

In one embodiment, a semiconductor structure includes a first set of transistors in a first level, the first set of transistors having a first gate pitch and a first cell height, and a second set of transistors in a second level, the second set of transistors having a second gate pitch and a second cell height. The second level is vertically stacked over the first level, the first gate pitch is different than the second gate pitch, and the first cell height is different than the second cell height.

In another embodiment, a semiconductor structure includes a first set of transistors in a first level, the first set of transistors having a first gate pitch and a first cell height, a second set of transistors in a second level, the second set of transistors having a second gate pitch and a second cell height, wherein the second level is vertically stacked over the first level, and a middle-of-line contact between a first region of one of the transistors in the first set of transistors in the first level and a second region of one of the transistors in the second set of transistors in the second level, the first region at least partially overlapping the second region.

In another embodiment, an integrated circuit includes a stacked transistor structure including a first set of transistors in a first level, the first set of transistors having a first gate pitch and a first cell height, and a second set of transistors in a second level, the second set of transistors having a second gate pitch and a second cell height. The second level is vertically stacked over the first level, the first gate pitch is different than the second gate pitch, and the first cell height is different than the second cell height.

### BRIEF DESCRIPTION OF THE DRAWINGS

FIG. 1A depicts a first cross-sectional view of a first set of transistors with a first gate pitch and a first cell height formed over a first substrate, according to an embodiment of the invention.

FIG. 1B depicts a second cross-sectional view of the first set of transistors with the first gate pitch and the first cell height formed over the first substrate, according to an embodiment of the invention.

FIG. 2A depicts a first cross-sectional view of the structure of FIGS. 1A and 1B following bonding to a semiconductor stack and a second substrate, according to an embodiment of the invention.

FIG. 2B depicts a second cross-sectional view of the structure of FIGS. 1A and 1B following bonding to the semiconductor stack and the second substrate, according to an embodiment of the invention.

FIG. 3A depicts a first cross-sectional view of the structure of FIGS. 2A and 2B following removal of the second substrate, according to an embodiment of the invention.

FIG. 3B depicts a second cross-sectional view of the structure of FIGS. 2A and 2B following the removal of the second substrate, according to an embodiment of the invention.

FIG. 4A depicts a first cross-sectional view of the structure of FIGS. 3A and 3B following formation of a second set of transistors with a second gate pitch and a second cell height, according to an embodiment of the invention.

FIG. 4B depicts a second cross-sectional view of the structure of FIGS. 3A and 3B following the formation of the second set of transistors with the second gate pitch and the second cell height, according to an embodiment of the invention.

FIG. 5A depicts a first cross-sectional view of the structure of FIGS. 4A and 4B following formation of middle-of-line contacts, according to an embodiment of the invention.

FIG. 5B depicts a second cross-sectional view of the structure of FIGS. 4A and 4B following the formation of the middle-of-line contacts, according to an embodiment of the invention.

FIG. 6A depicts a first cross-sectional view of the structure of FIGS. 5A and 5B following formation of a first set of back-end-of-line interconnects and bonding to a carrier wafer, according to an embodiment of the invention.

FIG. 6B depicts a second cross-sectional view of the structure of FIGS. 5A and 5B following the formation of the first set of back-end-of-line interconnects and the bonding to the carrier wafer, according to an embodiment of the invention.

FIG. 7A depicts a first cross-sectional view of the structure of FIGS. 6A and 6B following removal of the first substrate, according to an embodiment of the invention.

FIG. 7B depicts a second cross-sectional view of the structure of FIGS. 6A and 6B following the removal of the first substrate, according to an embodiment of the invention.

FIG. 8A depicts a first cross-sectional view of the structure of FIGS. 7A and 7B following removal of an etch stop layer and semiconductor material, according to an embodiment of the invention.

FIG. 8B depicts a second cross-sectional view of the structure of FIGS. 7A and 7B following the removal of the etch stop layer and the semiconductor material, according to an embodiment of the invention.

FIG. 9A depicts a first cross-sectional view of the structure of FIGS. 8A and 8B following formation of a backside interlayer dielectric layer, according to an embodiment of the invention.

FIG. 9B depicts a second cross-sectional view of the structure of FIGS. 8A and 8B following the formation of the backside interlayer dielectric layer, according to an embodiment of the invention.

FIG. 10A depicts a first cross-sectional view of the structure of FIGS. 9A and 9B following formation of backside contacts, according to an embodiment of the invention.

FIG. 10B depicts a second cross-sectional view of the structure of FIGS. 9A and 9B following the formation of the backside contacts, according to an embodiment of the invention.

FIG. 11A depicts a first cross-sectional view of the structure of FIGS. 10A and 10B following formation of a second set of back-end-of-line interconnects, according to an embodiment of the invention.

FIG. 11B depicts a second cross-sectional view of the structure of FIGS. 10A and 10B following the formation of the second set of back-end-of-line interconnects, according to an embodiment of the invention.

FIG. 12A depicts a cross-sectional view of source/drain regions and contacts thereto between cell boundaries, according to an embodiment of the invention.

FIG. 12B depicts a first cross-sectional view of stacked source/drain regions and contacts thereto between cell boundaries, according to an embodiment of the invention.

FIG. 12C depicts a second cross-sectional view of stacked source/drain regions and contacts thereto between cell boundaries, according to an embodiment of the invention.

FIG. 12D depicts a third cross-sectional view of stacked source/drain regions and contacts thereto between cell boundaries, according to an embodiment of the invention.

FIG. 13 shows an integrated circuit comprising stacked transistor structures with hybrid gate pitch, according to an embodiment of the invention.

### DETAILED DESCRIPTION

Illustrative embodiments of the invention may be described herein in the context of illustrative methods for forming stacked transistor structures with hybrid gate pitch, along with illustrative apparatus, systems and devices formed using such methods. However, it is to be understood that embodiments of the invention are not limited to the illustrative methods, apparatus, systems and devices but instead are more broadly applicable to other suitable methods, apparatus, systems and devices.

A field-effect transistor (FET) is a transistor having a source, a gate, and a drain, and having action that depends on the flow of carriers (electrons or holes) along a channel that runs between the source and drain. Current through the channel between the source and drain may be controlled by a transverse electric field under the gate.

FETs are widely used for switching, amplification, filtering, and other tasks. FETs include metal-oxide-semiconductor (MOS) FETs (MOSFETs). Complementary MOS (CMOS) devices are widely used, where both n-type and p-type transistors (nFET and pFET) are used to fabricate logic and other circuitry. Source and drain regions of a FET are typically formed by adding dopants to target regions of a semiconductor body on either side of a channel, with the gate being formed above the channel. The gate includes a gate dielectric over the channel and a gate conductor over the gate dielectric. The gate dielectric is an insulator material that prevents large leakage current from flowing into the channel when voltage is applied to the gate conductor while allowing applied gate voltage to produce a transverse electric field in the channel.

Various techniques may be used to reduce the size of FETs. One technique is through the use of fin-shaped channels in FinFET devices. Before the advent of FinFET arrangements, CMOS devices were typically substantially planar along the surface of the semiconductor substrate, with the exception of the FET gate disposed over the top of the channel. FinFETs utilize a vertical channel structure, increasing the surface area of the channel exposed to the gate. Thus, in FinFET structures the gate can more effectively control the channel, as the gate extends over more than one side or surface of the channel. In some FinFET arrangements, the gate encloses three surfaces of the three-dimensional channel, rather than being disposed over just the top surface of a traditional planar channel.

Another technique useful for reducing the size of FETs is through the use of stacked nanosheet channels formed over a semiconductor substrate. Stacked nanosheet channels may be two-dimensional nanostructures, such as sheets having a thickness range on the order of 1 to 100 nanometers (nm). Nanosheets and nanowires are viable options for scaling to 7 nm and beyond. A general process flow for formation of a nanosheet stack involves removing sacrificial layers, which may be formed of silicon germanium (SiGe), between sheets of channel material, which may be formed of silicon (Si).

Increasing demand for high density and performance in integrated circuit devices requires development of new structural and design features, including shrinking gate lengths and other reductions in size or scaling of devices. Continued scaling, however, is reaching limits of conventional fabrication techniques.

Stacking transistors in a vertical direction gives an additional dimension for CMOS area scaling. There are various challenges, however, in forming stacked FET structures. One challenge is in locally wiring “bottom” transistor devices to “top” transistor devices, or vice versa. Conventional approaches either lead to poor performance (e.g., when trying to use extremely small contacts to save area for scaling and parasitic capacitance) or larger cell size (e.g., when trying to make a robust contact size and contact spacing). Another challenge is in forming multiple threshold voltages (Vt) with a monolithic fabrication process. Even with bonded flows, bottom to top misalignment (e.g., including misalignment in the range of 2-3 nm) will break the process margin, because there is a need to make fine contacts through the top to the bottom devices, at very tight pitches (e.g., both gate pitch and metallization layer pitches). There is thus a need for solutions for forming stacked transistor structures with improvements in transistor density with design flexibility.

Illustrative embodiments provide a stacked transistor structure with hybrid gate pitch. In some embodiments, a semiconductor device comprises a first or upper level of transistors (e.g., CMOS devices) with a first gate pitch and a first cell height, and a second or lower level of transistors (e.g., CMOS devices) with a second gate pitch and a second cell height, where the first gate pitch is different than the second gate pitch. The first cell height may also be different than the second cell height. Middle-of-line (MOL) connections between the first/upper and second/lower transistors may be formed in some locations where source/drain regions for the first/upper transistors and source/drain regions for the second/lower transistors at least partially overlap with each other, and/or where the source/drain regions of the first/upper transistors and gate regions of the second/lower transistors at least partially overlap one another. One or more deep vias may be formed to connect frontside and backside interconnects (e.g., frontside back-end-of-line (BEOL) interconnects and backside BEOL interconnects). One or more backside interconnects may be connected to the second/lower transistors through backside contacts. The frontside interconnects may comprise both power delivery and signal wirings. The backside interconnects may also comprise both power delivery and signal wirings.

A process flow for forming stacked transistors with hybrid gate pitch may include forming a first set of transistors (e.g., a bottom or lower level) with a first gate pitch and a first cell height, and forming a second set of transistors (e.g., a top or upper level) with a second gate pitch and a second cell height, where the first gate pitch is different than the second gate pitch. The first cell height may also be different than the second cell height. The process flow may also include forming MOL contacts for the first set of transistors, and forming connections between source/drain regions of one or more of the transistors in the first set of transistors and source/drain regions of one or more of the transistors in the second set of transistors only at locations where such source/drain regions at least partially overlap one another. The process flow may further include forming connections between source/drain regions of one or more of the transistors in the first set of transistors and gate regions of one or more of the transistors in the second set of transistors only at locations where such source/drain and gate regions at least partially overlap one another. The process flow may further include forming deep MOL vias (e.g., from a top or frontside of the structure through and into shallow trench isolation regions for the second set of transistors). The process flow may also include forming frontside BEOL interconnects, bonding the structure to a carrier wafer, performing a wafer flip, removing the substrate, and forming backside contacts and backside BEOL interconnects. Connections may also be formed to connect the backside contacts and/or backside BEOL interconnects with one or more of the deep MOL vias.

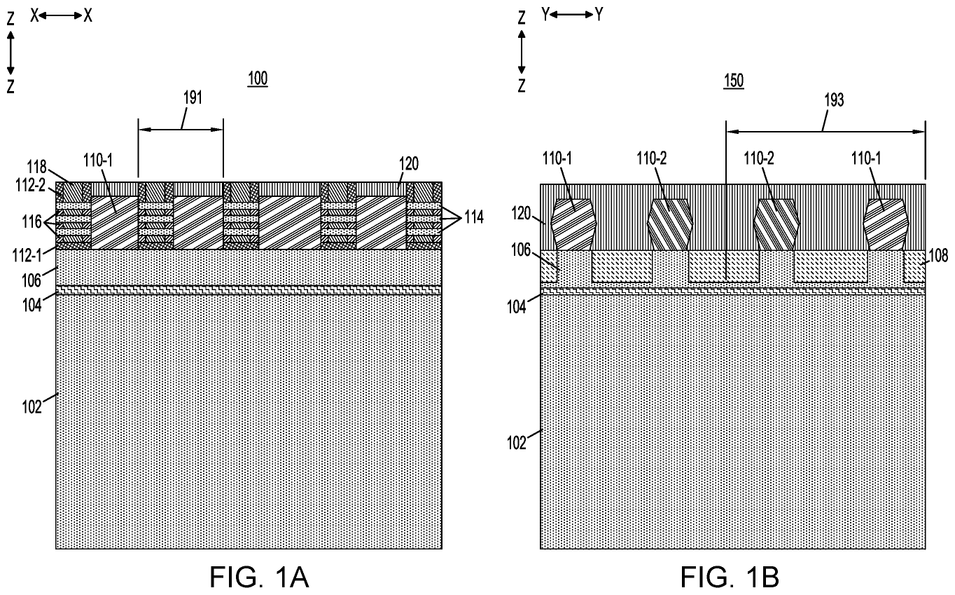

An illustrative process flow for forming stacked transistor structures with hybrid gate pitch will now be described in further detail with respect to FIGS. 1A through 11B.

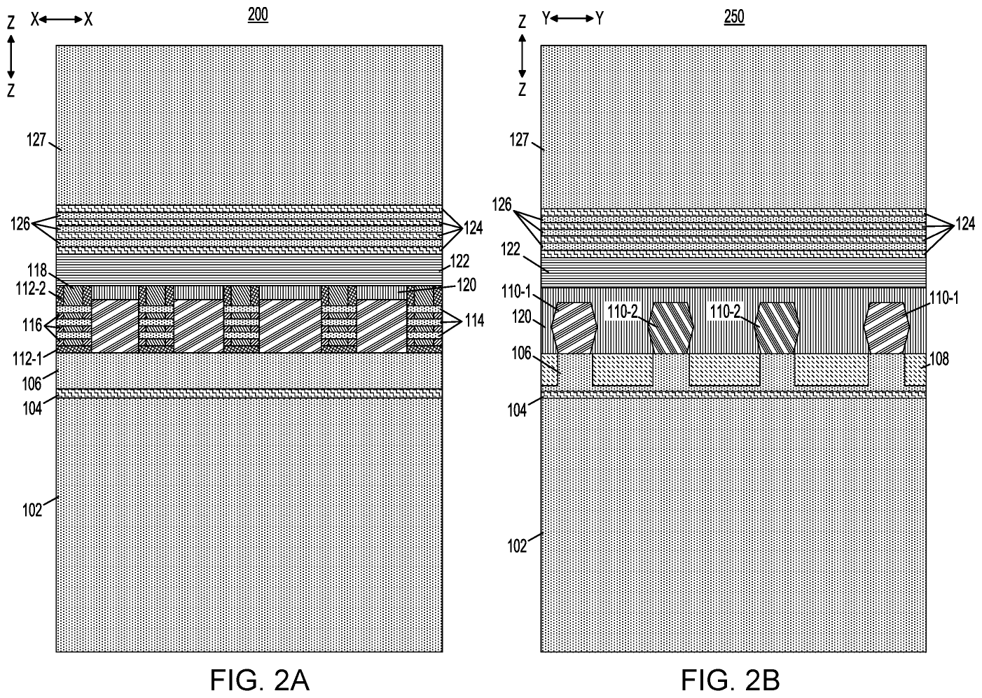

FIGS. 1A and 1B show respective cross-sectional views 100 and 150 of a structure following formation of a first set of transistors (e.g., CMOS devices) with a first gate pitch and a first cell height. The cross-sectional view 100 of FIG. 1A (and subsequent cross-sectional views of FIGS. 2A, 3A, 4A, 5A, 6A, 7A, 8A, 9A, 10A and 11A) is taken across gate structures of the first set of transistors, while the cross-sectional view 150 of FIG. 1B (and subsequent cross-sectional views of FIGS. 2B, 3B, 4B, 5B, 6B, 7B, 8B, 9B, 10B and 11B) is taken across source/drain regions of the first set of transistors. The structure of FIGS. 1A and 1B includes a first substrate 102, an etch stop layer 104, a semiconductor layer 106, shallow trench isolation (STI) regions 108, first source/drain regions 110-1, second source/drain regions 110-2, spacers 112-1 and 112-2, channel layers 114, inner spacers 116, gate regions 118, and interlayer dielectric (ILD) layer 120.

The first substrate 102 and semiconductor layer 106 may be formed of any suitable semiconductor structure, including various silicon-containing materials including but not limited to silicon (Si), silicon germanium (SiGe), silicon germanium carbide (SiGeC), silicon carbide (SiC) and multi-layers thereof. Although silicon is the predominantly used semiconductor material in wafer fabrication, alternative semiconductor materials can be employed as additional layers, such as, but not limited to, germanium (Ge), gallium arsenide (GaAs), gallium nitride (GaN), SiGe, cadmium telluride (CdTe), zinc selenide (ZnSe), etc.

The etch stop layer 104 may comprise a buried oxide (BOX) layer or silicon germanium (SiGe), or another suitable material such as a III-V semiconductor epitaxial layer. The etch stop layer 104 may have a height (in direction Z) in the range of 10 to 30 nm.

The channel layers 114 may be formed of similar materials as the first substrate 102 and the semiconductor layer 106. Initially, a nanosheet stack including alternative sacrificial layers and the channel layers 114 may be formed, with the sacrificial layers later being removed and replaced with the gate regions 118. Each of the channel layers 114 may have a thickness (in direction Z) in the range of 4-10 nm.

The STI regions 108 may be formed by patterning a masking layer over the nanosheet stack (e.g., of the alternating sacrificial layers and the channel layers 114), and etching exposed portions of the nanosheet stack and through a portion of the semiconductor layer 106, followed by deposition or other formation of material for the STI regions 108. The STI regions 108 may be formed of a dielectric material such as silicon dioxide (SiO₂), silicon oxycarbide (SiOC), silicon oxynitride (SiON), etc. The STI regions 108 may have a height (in direction Z) in the range of 20 to 100 nm.

The spacers 112-1 and 112-2 may be formed as part of dummy gate processing, where dummy gates are formed over the nanosheet stack, with the sacrificial layers of the nanosheet stack being selectively removed followed by formation of material of the spacers 112-1 and 112-2. The spacer 112-1 provides a bottom insulator, and the spacer 112-2 provides gate sidewall spacers. The spacers 112-1 and 112-2 may be formed of any suitable insulator such as SiN, silicon boron carbide nitride (SiBCN), silicon oxycarbonitride (SiOCN), etc. The spacer 112-1 may have a height (in direction Z) in the range of 6-15 nm, and the spacer 112-2 may have a uniform thickness in the range of 2-10 nm.

The first source/drain regions 110-1 and the second source/drain regions 110-2 (collectively, source/drain regions 110) may be formed after formation of dummy gates over the nanosheet stack. Sacrificial layers of the nanosheet stack are indented (e.g., using an indent etch process), followed by formation of the inner spacers 116 in the regions formed by the indent etch of the sacrificial layers of the nanosheet stack. The inner spacers 116 may be formed of silicon nitride (SiN) or another suitable material such as SiBCN, silicon carbide oxide (SiCO), SiOCN, etc. The inner spacers 116 may have widths (in direction X) in the range of 2-10 nm, and may have heights (in direction Z) matching that of the sacrificial layers of the nanosheet stack.

The source/drain regions 110 may be formed using epitaxial growth processes, and thus may also be referred to as epitaxial layers. The first source/drain regions 110-1 and the second source/drain regions 110-2 may be suitably doped, such as using ion implantation, gas phase doping, plasma doping, plasma immersion ion implantation, cluster doping, infusion doping, liquid phase doping, solid phase doping, etc. In some embodiments, the first source/drain regions 110-1 provide n-type source/drain regions while the second source/drain regions 110-2 provide p-type source drain regions, or vice versa. N-type dopants may be selected from a group of phosphorus (P), arsenic (As) and antimony (Sb), and p-type dopants may be selected from a group of boron (B), boron fluoride (BF₂), gallium (Ga), indium (In), and thallium (Tl). In some embodiments, the epitaxy process used to form the source/drain regions 110 comprises in-situ doping (dopants are incorporated in epitaxy material during epitaxy). Epitaxial materials may be grown from gaseous or liquid precursors. Epitaxial materials may be grown using vapor-phase epitaxy (VPE), molecular-beam epitaxy (MBE), liquid-phase epitaxy (LPE), rapid thermal chemical vapor deposition (RTCVD), metal organic chemical vapor deposition (MOCVD), ultra-high vacuum chemical vapor deposition (UHVCVD), low-pressure chemical vapor deposition (LPCVD), limited reaction processing CVD (LRPCVD), or other suitable processes. Epitaxial silicon, silicon germanium (SiGe), germanium (Ge), and/or carbon doped silicon (Si:C) silicon can be doped during deposition (in-situ doped) by adding dopants, such as n-type dopants (e.g., phosphorus or arsenic) or p-type dopants (e.g., boron or gallium), depending on the type of transistor to be formed. The dopant concentration in the source/drain can range from 1×10¹⁹ cm⁻³ to 3×10²¹ cm⁻³, or preferably between 2×10²⁰ cm⁻³ to 3×10²¹ cm⁻³. The source/drain regions 110 may each have a width (in direction Y) in the range of 10 to 50 nm, and height (in direction Z) in the range of 30 to 100 nm.

After the source/drain regions 110 are formed, the gate regions 118 may be formed. The dummy gates and sacrificial layers of the nanosheet stack may be removed, followed by formation of a gate stack for the gate regions 118 (e.g., using high-k metal gate (HKMG) processing). The gate stack may comprise a gate dielectric layer and a gate conductor layer. The gate dielectric layer may be formed of a high-k dielectric material. Examples of high-k materials include but are not limited to metal oxides such as HfO₂, hafnium silicon oxide (Hf—Si—O), hafnium silicon oxynitride (HfSiON), lanthanum oxide (La₂O₃), lanthanum aluminum oxide (LaAlO₃), zirconium oxide (ZrO₂), zirconium silicon oxide, zirconium silicon oxynitride, tantalum oxide (Ta₂O₅), titanium oxide (TiO₂), barium strontium titanium oxide, barium titanium oxide, strontium titanium oxide, yttrium oxide (Y₂O₃), aluminum oxide (Al₂O₃), lead scandium tantalum oxide, and lead zinc niobate. The high-k material may further include dopants such as lanthanum (La), aluminum (Al), and magnesium (Mg). The gate dielectric layer may have a uniform thickness in the range of 1 nm to 3 nm.

The gate conductor layer may include a metal gate or work function metal (WFM). The WFM for the gate conductor layer may be titanium (Ti), titanium nitride (TiN), tantalum (Ta), tantalum nitride (TaN), aluminum (Al), titanium aluminum (TiAl), titanium aluminum carbon (TiAlC), a combination of Ti and Al alloys, a stack which includes a barrier layer (e.g., of TiN, TaN, etc.) followed by one or more of the aforementioned WFM materials, etc. It should be appreciated that various other materials may be used for the gate conductor layer as desired.

The ILD layer 120 may be formed surrounding the source/drain regions 110 as illustrated. The ILD layer 120 may be formed of any suitable isolating material, such as SiO₂, SiOC, SiON, etc.

The first set of transistors shown in the structure of FIGS. 1A and 1B has a first gate pitch represented by distance 191, and a first cell height (e.g., for a CMOS cell comprising an nFET and a pFET) represented by distance 193.

FIGS. 2A and 2B show respective cross-sectional views 200 and 250 of the structure of FIGS. 1A and 1B following bonding, via a bonding oxide 122 to another nanosheet stack including sacrificial layers 124 and channel layers 126 and a second substrate 127. The bonding oxide 122 may be formed of a dielectric material such as an oxide or a nitride, and may have a height (in direction Z) in the range of 20 to 100 nm. The sacrificial layers 124 may be formed of SiGe or another suitable material which may be etched or removed selected to the material of the channel layers 126. The sacrificial layers 124 may have a height (in direction Z) in the range of 6-15 nm. The channel layers 126 may be formed of similar materials and with similar sizing as that of the channel layers 114. The second substrate 127 may be formed of similar materials as the first substrate 102.

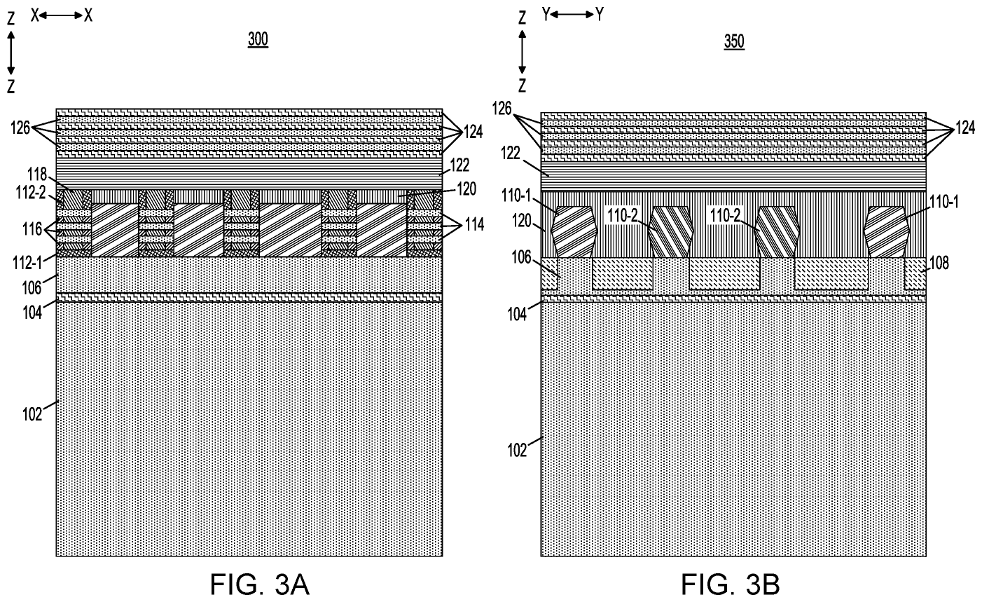

FIGS. 3A and 3B show respective cross-sectional views 300 and 350 of the structure of FIGS. 2A and 2B following removal of the second substrate 127. The second substrate 127 may be removed using a combination of processes such as Si grinding, chemical mechanical planarization (CMP) dry etching, wet etching or other suitable processing, which stops on the top-most one of the sacrificial layers 124.

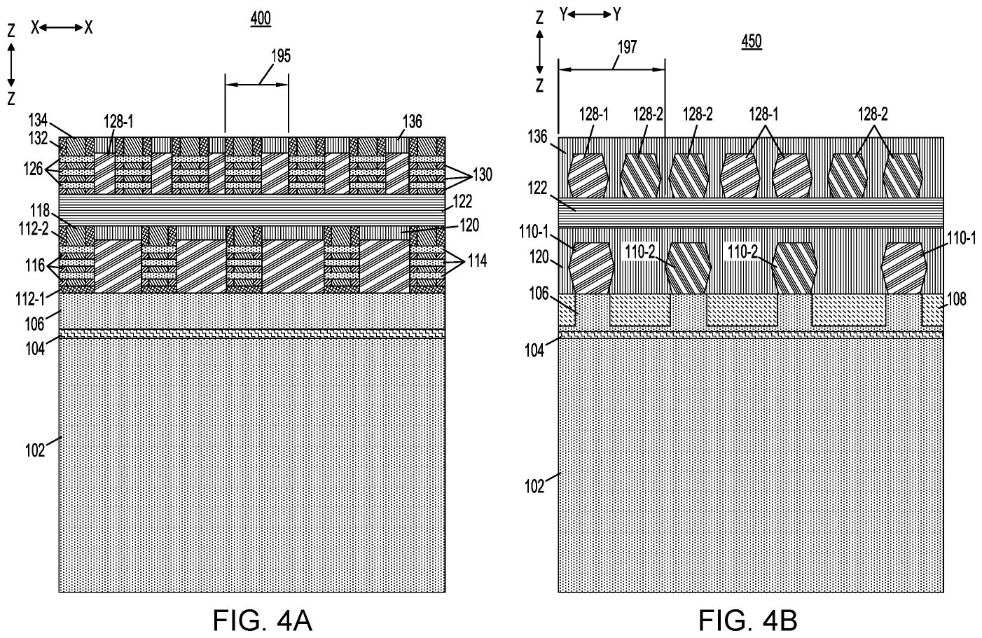

FIGS. 4A and 4B show respective cross-sectional views 400 and 450 of the structure of FIGS. 3A and 3B following formation of a second set of transistors with a second gate pitch and a second cell height. The second set of transistors may be formed using substantially similar processing as that described above with respect to the first set of transistors. Forming the second set of transistors includes formation of first source/drain regions 128-1, second source/drain regions 128-2, inner spacers 130, spacers 132, gate regions 134 and ILD layer 136.

The first source/drain regions 128-1 and second source/drain regions 128-2 (collectively, source/drain regions 128) may be formed using similar processing as that described above with respect to the source/drain regions 110. The first source/drain regions 128-1 may comprise n-type source/drain regions while the second source/drain regions 128-2 may comprise p-type transistors, or vice versa. The inner spacers 130, the gate regions 134 and the ILD layer 136 may be formed of similar materials and with similar sizing as that described above with respect to the inner spacers 116, the gate regions 118 and the ILD layer 120, respectively.

The second set of transistors shown in the structure of FIGS. 4A and 4B has a second gate pitch represented by distance 195, and a second cell height represented by distance 197. The second gate pitch is illustratively smaller than the first gate pitch (e.g., distance 195 is less than distance 191), and the second cell height is illustratively smaller than the first cell height (e.g., distance 197 is less than distance 193). Further, while FIGS. 1A-4B show an example where the first set of transistors has a larger gate pitch than the second set of transistors, this is not a requirement. In other embodiments, the first set of transistors may have a smaller gate pitch than the second set of transistors.

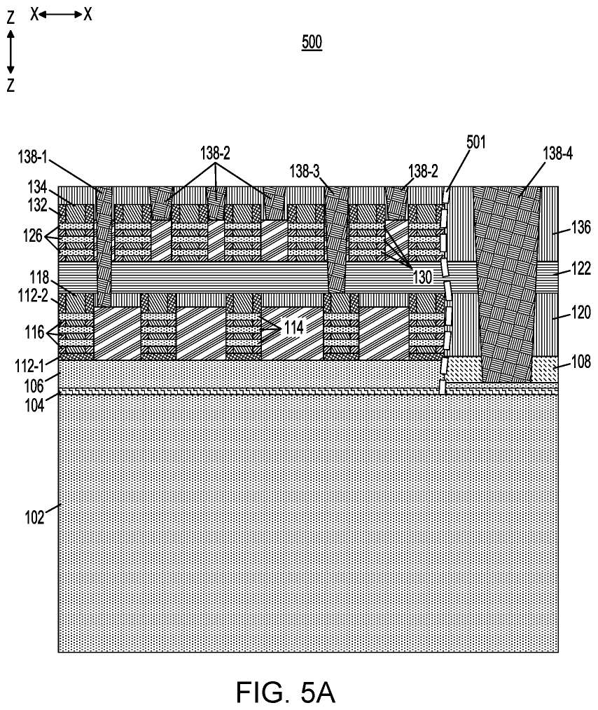

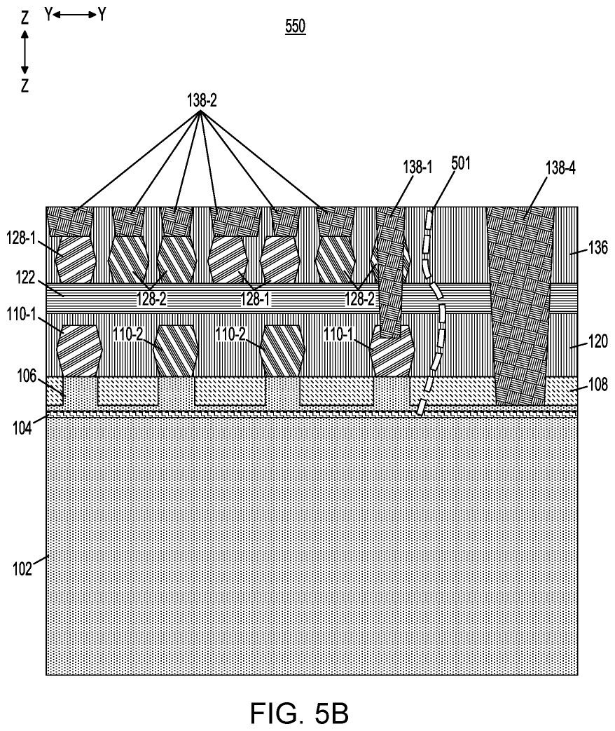

FIGS. 5A and 5B show respective cross-sectional views 500 and 550 of the structure of FIGS. 4A and 4B following formation of MOL contacts (e.g., formed of contact metals including a silicide liner such as titanium (Ti), nickel (Ni), a nickel-platinum alloy (NiPt), a metal adhesion layer such as titanium nitride (TiN), and a low resistance metal fill such as tungsten (W), cobalt (Co), or ruthenium (Ru)), including a first MOL contact 138-1 (e.g., a top source/drain region to bottom/source drain region connection), second MOL contacts 138-2 (top source/drain region connections), a third MOL contact 138-3 (e.g., a top source/drain region to bottom gate region connection), and a fourth MOL contact 138-4 (e.g., a deep via connection). The fourth MOL contact 138-4 extends from a top side of the structure into the STI region 108 as shown, and may have a width (in directions X and Y) in the range of 30 to 500 nm. The fourth MOL contact 138-4 may be formed on an outer edge of the area where the first and second sets of transistors are formed, represented by boundary line 501 in FIGS. 5A and 5B. The first MOL contact 138-1 is formed in an area where one of the source/drain regions 128-1 at least partially overlaps one of the source/drain regions 110-1. The third MOL contact 138-3 is formed in an area where one of the source/drain regions 128-2 at least partially overlaps one of the gate regions 118.

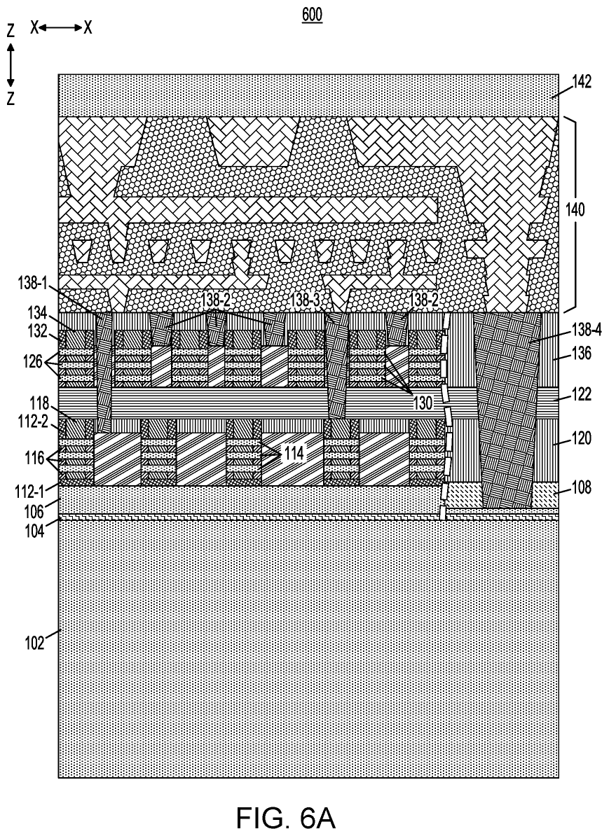

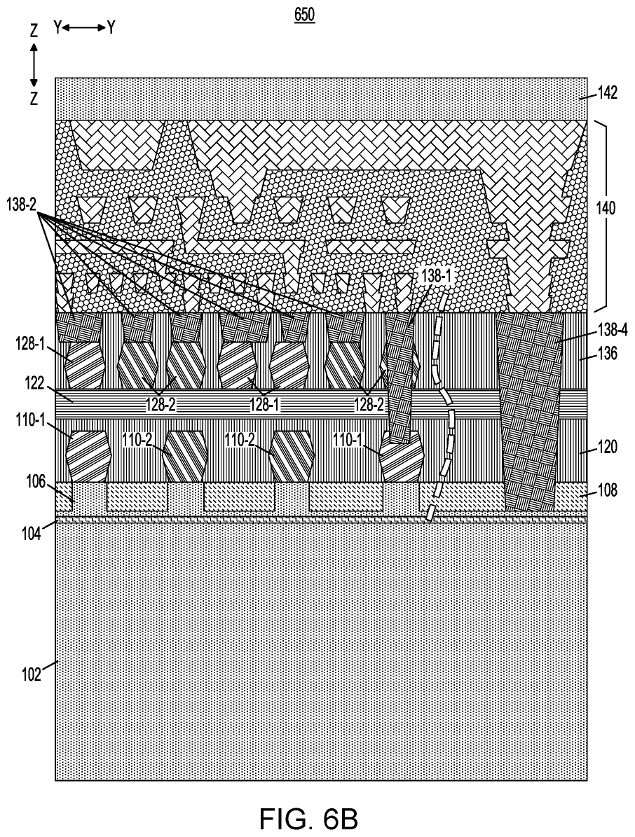

FIGS. 6A and 6B show respective cross-sectional views 600 and 650 of the structure of FIGS. 5A and 5B following formation of a first set of BEOL interconnects 140 and a carrier wafer 142 over a top or frontside of the structure (e.g., over the ILD layer 136). The first set of BEOL interconnects 140 may include various metallization levels (e.g., M1, M2, etc.) and via levels (e.g., V1, V2, etc.) which provide a desired interconnection of the MOL contacts. The carrier wafer 142 may be formed of similar materials as the first substrate 102. The first set of BEOL interconnects 140 includes the via and metallization levels (e.g., formed of a conducting material such as copper (Cu)) surrounded by a dielectric material such as a low-k oxide. It should be noted that the particular interconnections for the first set of BEOL interconnects 140 may include more or fewer layers, and further that connections to deep via connections including the fourth MOL contact 138-4 may happened at higher or lower BEOL levels.

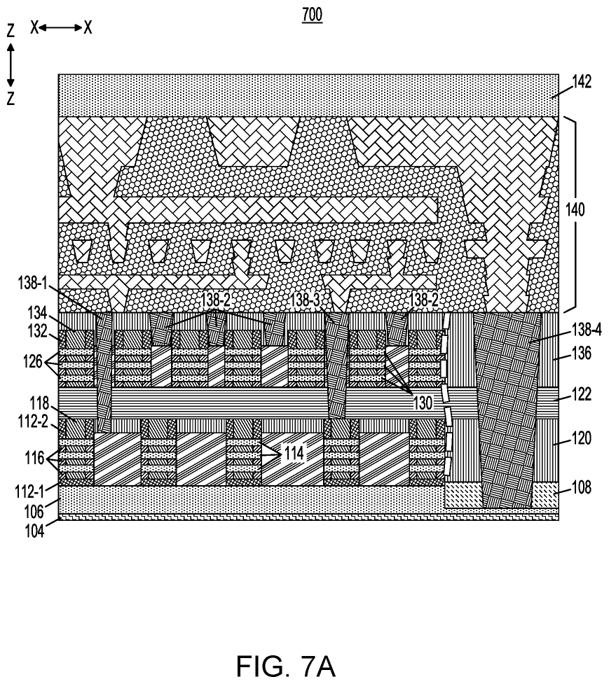

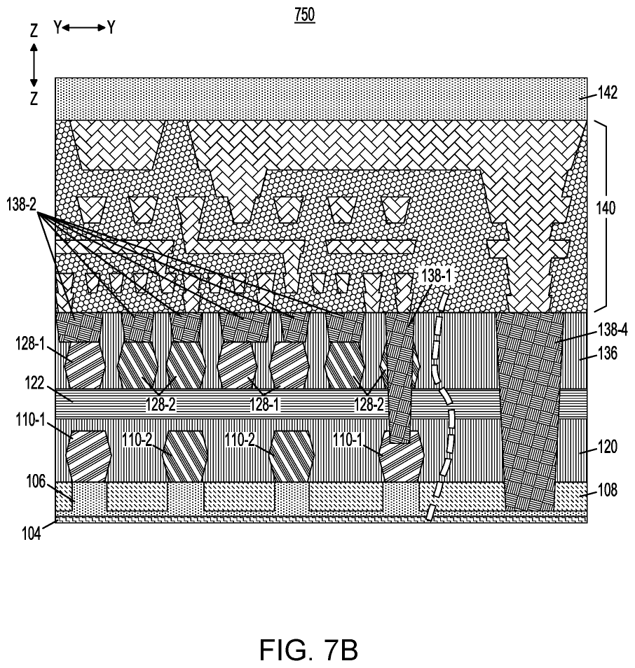

FIGS. 7A and 7B show respective cross-sectional views 700 and 750 of the structure of FIGS. 6A and 6B following removal of the first substrate 102. The first substrate 102 may be removed using a combination of Si grinding, CMP, dry etch, wet etch or other suitable processing following a wafer flip using the carrier wafer 142.

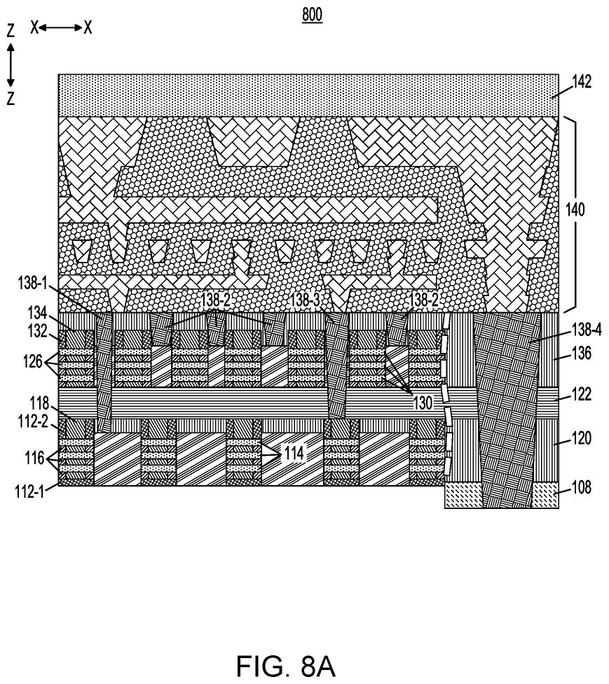

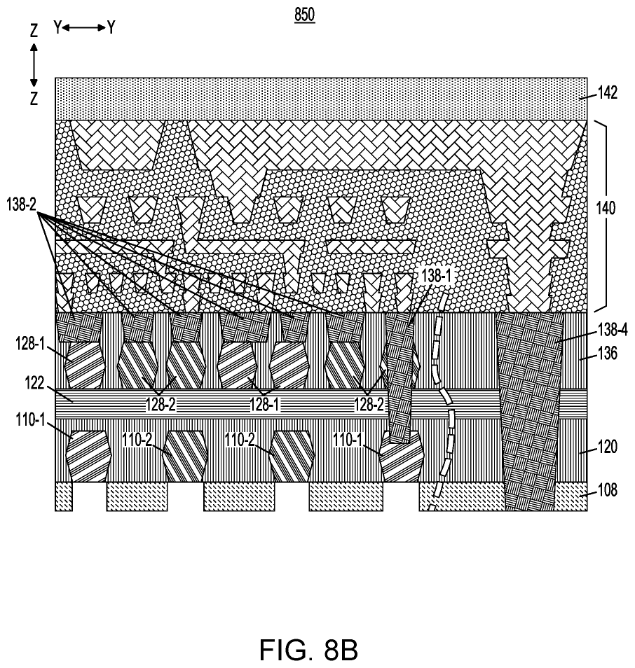

FIGS. 8A and 8B show respective cross-sectional views 800 and 850 of the structure of FIGS. 7A and 7B following removal of the etch stop layer 104 and the semiconductor layer 106. The etch stop layer 104 and semiconductor layer 106 may be removed using RIE or other suitable etch processes.

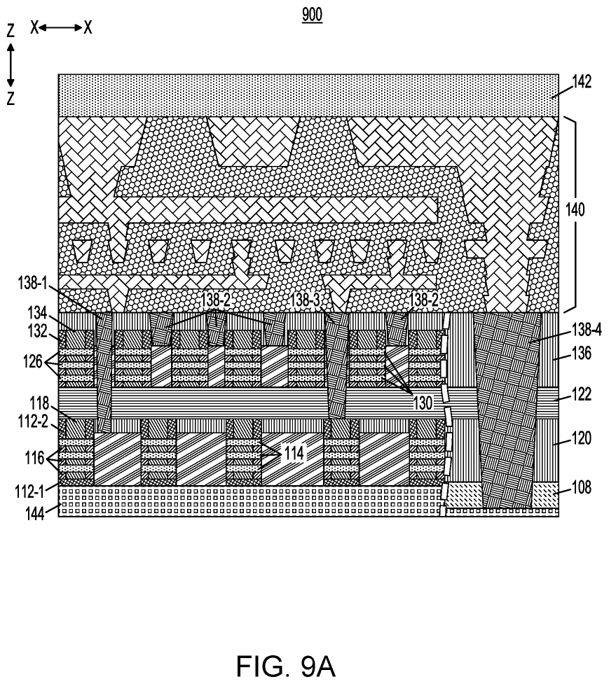

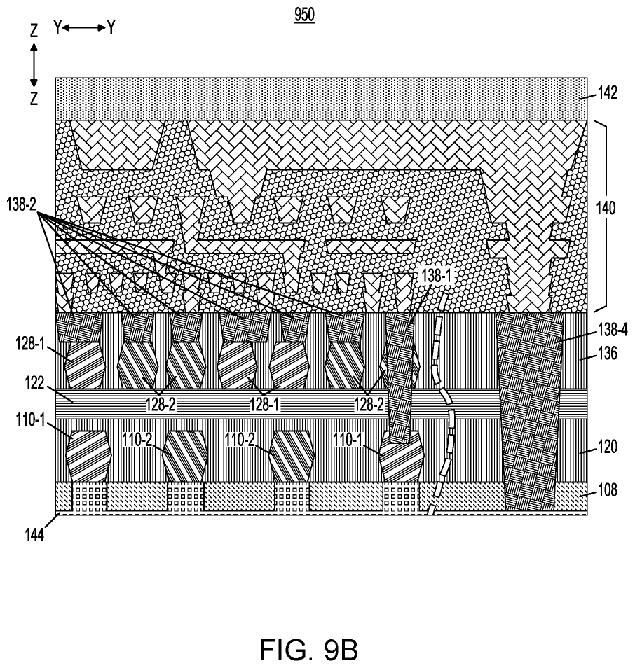

FIGS. 9A and 9B show respective cross-sectional views 900 and 950 of the structure of FIGS. 8A and 8B following formation of a backside ILD layer 144 (e.g., in regions exposed by removal of the semiconductor layer 106). The backside ILD layer 144 may be formed of similar materials as the ILD layers 120 and 136. The backside ILD layer 144 may have a height (in direction Z) in the range of 20 to 150 nm.

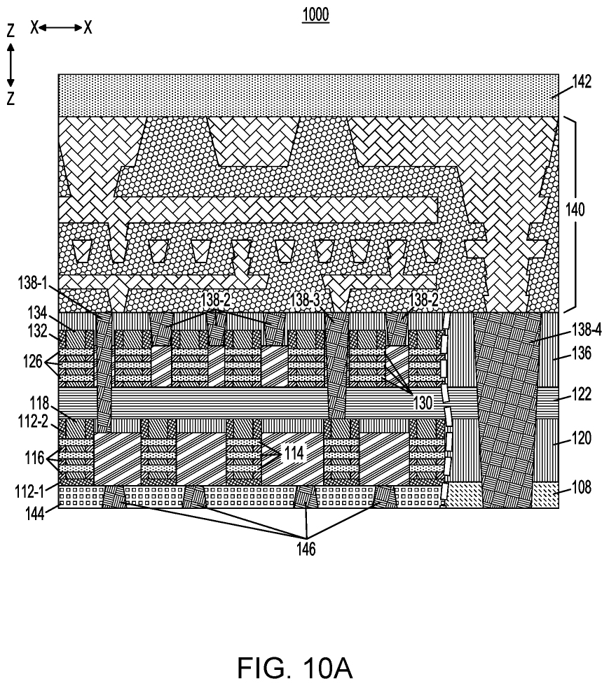

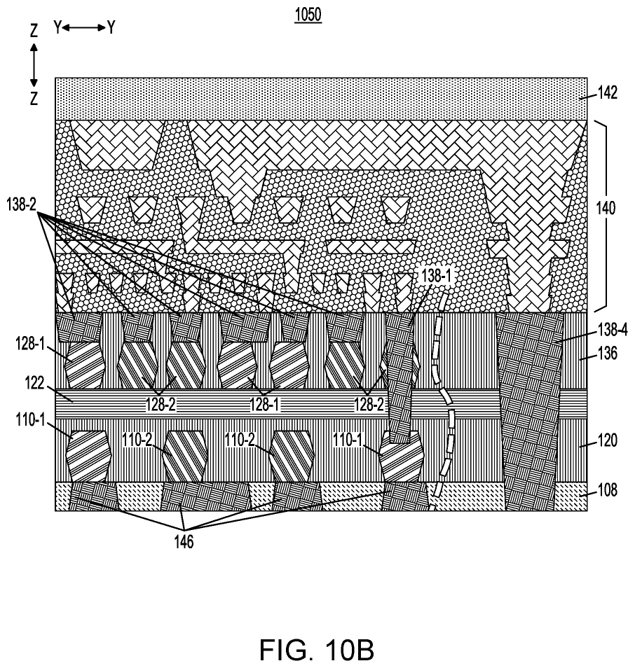

FIGS. 10A and 10B show respective cross-sectional views 1000 and 1050 of the structure of FIGS. 9A and 9B following formation of backside contacts 146 to the source/drain regions 110 and the fourth MOL contact 138-4. The backside contacts 146 may be formed of similar material as the MOL contacts. The backside contacts 146 may be formed by patterning a mask over the backside ILD layer 144, and etching exposed portions of the backside ILD layer 144 in order to provide openings to the source/drain regions 110, as well as the fourth MOL contact 138-4. It should be noted here that, with the relaxed or increased gate pitch of the first set of transistors, there is advantageously a wider process margin for the backside overlay needed for patterning openings in the backside ILD layer 144 for formation of the backside contacts 146. The backside of the structure may be planarized (e.g., using CMP) following formation of the backside contacts.

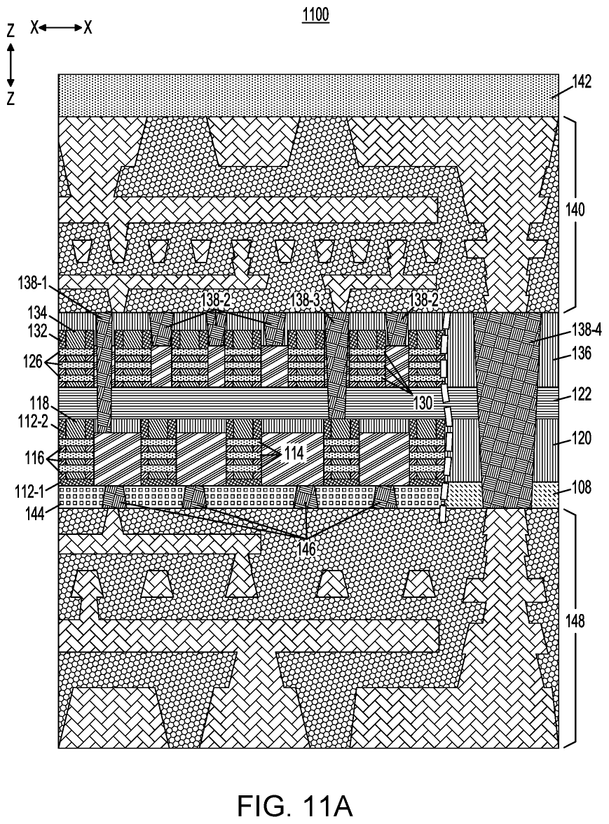

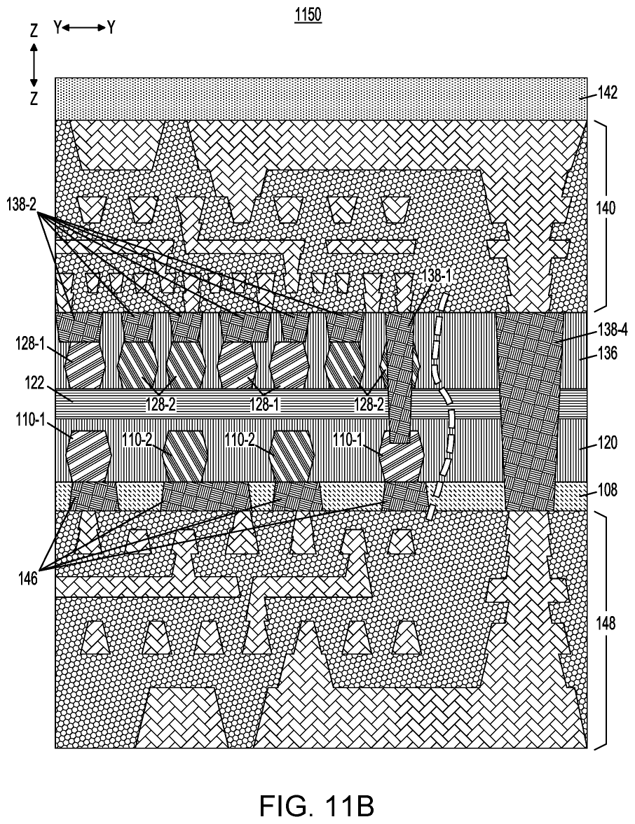

FIGS. 11A and 11B show respective cross-sectional views 1100 and 1150 of the structure of FIGS. 10A and 10B following formation of a second set of BEOL interconnects 148 over a bottom or backside of the structure (e.g., over the backside ILD layer 144). The second set of BEOL interconnects 148, similar to the first set of BEOL interconnects 140, may include various metallization levels (e.g., M1, M2, etc.) and via levels (e.g., V1, V2, etc.) which provide a desired interconnection of the backside contacts 146 and the fourth MOL contact 138-4. The second set of BEOL interconnects 148 includes the via and metallization levels (e.g., formed of a conducting material such as Cu surrounded by a dielectric material such as a low-k oxide). It should be noted that the particular interconnections for the second set of BEOL interconnects 148 may include more or fewer layers, and further that connections to deep via connections including the fourth MOL contact 138-4 may happened at higher or lower BEOL levels. It should further be noted here that, with the relaxed or increased gate pitch of the first set of transistors, there is advantageously a wider process margin and relaxed pitch for the backside contacts 146 and the second set of BEOL interconnects 148.

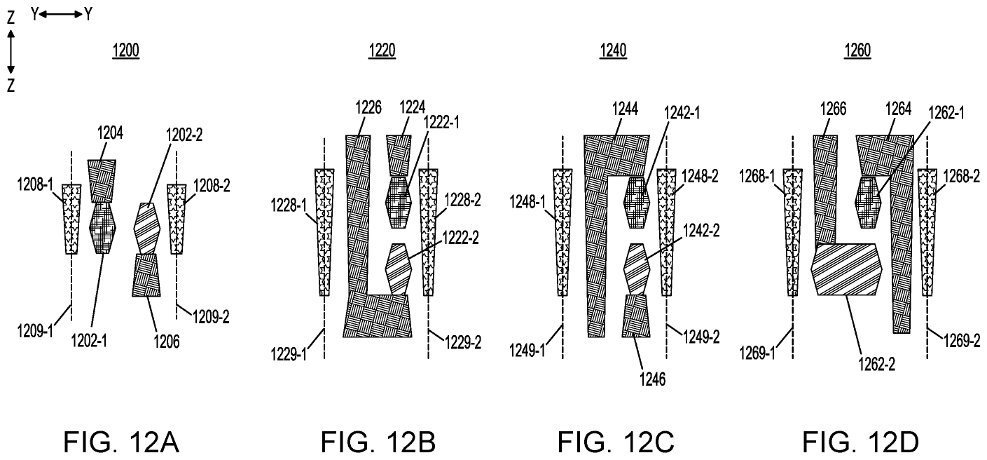

FIGS. 12A, 12B, 12C and 12D show respective cross-sectional views 1200, 1220, 1240 and 1260 illustrating scaling challenges associated with stacked transistor structures. The cross-sectional view 1200 of FIG. 12A illustrates a first source/drain region 1202-1 (e.g., an NFET source/drain region) and a second source/drain region 1202-2 (e.g., a PFET source/drain region) formed adjacent one another between cell boundaries 1208-1 and 1208-2, with center lines 1209-1 and 1209-2. A first contact 1204 is formed to the first source/drain region 1202-1 (e.g., from a frontside of the structure) and a second contact 1206 is formed to the second source/drain region 1202-2 (e.g., from a backside of the structure).

The cross-sectional view 1220 of FIG. 12B shows a first strategy for increased scaling of the structure shown in FIG. 12A, including a first source/drain region 1222-1 (e.g., an NFET source/drain region) and a second source/drain region 1222-2 (e.g., a PFET source/drain region) stacked on top of one another between cell boundaries 1228-1 and 1228-2, with center lines 1229-1 and 1229-2. A first contact 1224 is formed to the first source/drain region 1222-1 (e.g., from a frontside of the structure), and a second contact 1226 is formed to the second source/drain region 1222-2 (e.g., using a deep via that extends from the frontside of the structure and connects to a backside contact on the backside of the structure). In the structure of FIG. 12B, the cell height (e.g., of the first source/drain region 1222-1 and the second source/drain region 1222-2) is maintained and there is no performance benefit, but there are significant process challenges associated with formation of the second contact 1226.

The cross-sectional view 1240 of FIG. 12C shows a second strategy for increased scaling of the structure shown in FIG. 12A, including a first source/drain region 1242-1 (e.g., an NFET source/drain region) and a second source/drain region 1242-2 (e.g., a PFET source/drain region) stacked on top of one another between cell boundaries 1248-1 and 1248-2, with center lines 1249-1 and 1249-2. A first contact 1244 is formed to the first source/drain region 1242-1 (e.g., using a deep via that extends from a backside of the structure and extends to a frontside of the structure and connects to a frontside contact), and a second contact 1246 is formed to the second source/drain region 1242-2 (e.g., from the backside of the structure). In the structure of FIG. 12C, similar to the structure of FIG. 12B, the cell height (e.g., of the first source/drain region 1242-1 and the second source/drain region 1242-2) is maintained and there is no performance benefit, but there are significant process challenges associated with formation of the first contact 1244.

The cross-sectional view 1260 of FIG. 12D shows a third strategy for increased scaling of the structure shown in FIG. 12A, including a first source/drain region 1262-1 (e.g., an NFET source/drain region) and a second source/drain region 1262-2 (e.g., a PFET source/drain region) stacked on top of one another, with the second source/drain region 1262-2 being wider than the first source/drain region 1262-1, and where the first source/drain region 1262-1 and the second source/drain region 1262-2 are formed between cell boundaries 1268-1 and 1268-2, with center lines 1269-1 and 1269-2. A first contact 1264 is formed to the first source/drain region 1262-1 (e.g., using a deep via extending from a backside of the structure to a frontside of the structure interconnecting with a frontside contact), and a second contact 1266 is formed to the second source/drain region 1262-2 (e.g., from the frontside of the structure). In the structure of FIG. 12D, there is possibly a stronger “bottom” device associated with the second source/drain region 1262-2 which is wider than the first source/drain region 1262-1, but cell height is lost.

A fundamental issue with the stacked transistor approaches shown in FIGS. 12B, 12C and 12D is in locally wiring the top and bottom devices. Conventional approaches either lead to poor performance (e.g., when trying to use extremely small contacts to save area for scaling and parasitic capacitance) or larger cell size (e.g., when trying to make a robust contact size and contact spacing).

Semiconductor devices and methods for forming the same in accordance with the above-described techniques can be employed in various applications, hardware, and/or electronic systems. Suitable hardware and systems for implementing embodiments of the invention may include, but are not limited to, personal computers, communication networks, electronic commerce systems, portable communications devices (e.g., cell and smart phones), solid-state media storage devices, functional circuitry, etc. Systems and hardware incorporating the semiconductor devices are contemplated embodiments of the invention. Given the teachings provided herein, one of ordinary skill in the art will be able to contemplate other implementations and applications of embodiments of the invention.

In some embodiments, the above-described techniques are used in connection with semiconductor devices that may require or otherwise utilize, for example, complementary metal-oxide-semiconductors (CMOSs), metal-oxide-semiconductor field-effect transistors (MOSFETs), and/or fin field-effect transistors (FinFETs). By way of non-limiting example, the semiconductor devices can include, but are not limited to CMOS, MOSFET, and FinFET devices, and/or semiconductor devices that use CMOS, MOSFET, and/or FinFET technology.

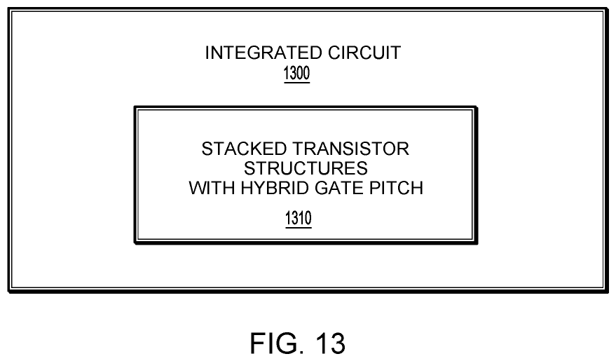

Various structures described above may be implemented in integrated circuits. The resulting integrated circuit chips can be distributed by the fabricator in raw wafer form (that is, as a single wafer that has multiple unpackaged chips), as a bare die, or in a packaged form. In the latter case the chip is mounted in a single chip package (such as a plastic carrier, with leads that are affixed to a motherboard or other higher level carrier) or in a multichip package (such as a ceramic carrier that has either or both surface interconnections or buried interconnections). In any case the chip is then integrated with other chips, discrete circuit elements, and/or other signal processing devices as part of either: (a) an intermediate product, such as a motherboard, or (b) an end product. The end product can be any product that includes integrated circuit chips, ranging from toys and other low-end applications to advanced computer products having a display, a keyboard or other input device, and a central processor. FIG. 13 shows an example integrated circuit 1300 which includes one or more stacked transistor structures 1310 with hybrid gate pitch.

In some embodiments, a semiconductor structure includes a first set of transistors in a first level, the first set of transistors having a first gate pitch and a first cell height, and a second set of transistors in a second level, the second set of transistors having a second gate pitch and a second cell height. The second level is vertically stacked over the first level, the first gate pitch is different than the second gate pitch, and the first cell height is different than the second cell height.

The first gate pitch may be greater than the second gate pitch.

The first cell height may be greater than the second cell height.

The semiconductor structure may further include a MOL contact between (i) a first source/drain region of one of the transistors in the first set of transistors in the first level and (ii) a second source/drain region of one of the transistors in the second set of transistors in the second level, wherein the first source/drain region at least partially overlaps the second source/drain region.

The semiconductor structure may further include a MOL contact between (i) a source/drain region of one of the transistors in the first set of transistors in the first level and (ii) a gate region of one of the transistors in the second set of transistors in the second level, wherein the source/drain region at least partially overlaps the gate region.

The semiconductor structure may further include at least one via connecting a first interconnect on a first side of the semiconductor structure below the first level and a second interconnect on a second side of the semiconductor structure above the second level.

The semiconductor structure may further include at least one interconnect on a first side of the semiconductor structure below the first level which connects to at least one transistor of the first set of transistors of the first level through one or more contacts below the first level.

The semiconductor structure may further include one or more interconnects on a first side of the semiconductor structure below the first level, the one or more interconnects on the first side of the semiconductor structure including a power delivery network and signal wirings.

The semiconductor structure may further include one or more interconnects on a second side of the semiconductor structure above the second level, the one or more interconnects on the second side of the semiconductor structure including a power delivery network and signal wirings.

In some embodiments, a semiconductor structure includes a first set of transistors in a first level, the first set of transistors having a first gate pitch and a first cell height, a second set of transistors in a second level, the second set of transistors having a second gate pitch and a second cell height, wherein the second level is vertically stacked over the first level, and a MOL contact between a first region of one of the transistors in the first set of transistors in the first level and a second region of one of the transistors in the second set of transistors in the second level, the first region at least partially overlapping the second region

The first gate pitch may be different than the second gate pitch, and the first cell height may be different than the second cell height.

The first region may include a first source/drain region of said one of the transistors in the first set of transistors and the second region includes a second source/drain region of said one of the transistors in the second set of transistors.

The first region may include a source/drain region of said one of the transistors in the first set of transistors and the second region includes a gate region of said one of the transistors in the second set of transistors.

The semiconductor structure may further include at least one via connecting a first interconnect on a first side of the semiconductor structure below the first level and a second interconnect on a second side of the semiconductor structure above the second level.

In some embodiments, an integrated circuit includes a stacked transistor structure including a first set of transistors in a first level, the first set of transistors having a first gate pitch and a first cell height, and a second set of transistors in a second level, the second set of transistors having a second gate pitch and a second cell height. The second level is vertically stacked over the first level, the first gate pitch is different than the second gate pitch, and the first cell height is different than the second cell height.

The first gate pitch may be greater than the second gate pitch.

The first cell height may be greater than the second cell height.

The integrated circuit may further include a MOL contact between (i) a first source/drain region of one of the transistors in the first set of transistors in the first level and (ii) a second source/drain region of one of the transistors in the second set of transistors in the second level, wherein the first source/drain region at least partially overlaps the second source/drain region.

The integrated circuit may further include a MOL contact between (i) a source/drain region of one of the transistors in the first set of transistors in the first level and (ii) a gate region of one of the transistors in the second set of transistors in the second level, wherein the source/drain region at least partially overlaps the gate region.

It should be understood that the various layers, structures, and regions shown in the figures are schematic illustrations that are not drawn to scale. In addition, for ease of explanation, one or more layers, structures, and regions of a type commonly used to form semiconductor devices or structures may not be explicitly shown in a given figure. This does not imply that any layers, structures, and regions not explicitly shown are omitted from the actual semiconductor structures. Furthermore, it is to be understood that the embodiments discussed herein are not limited to the particular materials, features, and processing steps shown and described herein. In particular, with respect to semiconductor processing steps, it is to be emphasized that the descriptions provided herein are not intended to encompass all of the processing steps that may be required to form a functional semiconductor integrated circuit device. Rather, certain processing steps that are commonly used in forming semiconductor devices, such as, for example, wet cleaning and annealing steps, are purposefully not described herein for economy of description.

Moreover, the same or similar reference numbers are used throughout the figures to denote the same or similar features, elements, or structures, and thus, a detailed explanation of the same or similar features, elements, or structures are not repeated for each of the figures. It is to be understood that the terms “approximately” or “substantially” as used herein with regard to thicknesses, widths, percentages, ranges, temperatures, times and other process parameters, etc., are meant to denote being close or approximate to, but not exactly. For example, the term “approximately” or “substantially” as used herein implies that a small margin of error is present, such as ±5%, preferably less than 2% or 1% or less than the stated amount.

In the description above, various materials, dimensions and processing parameters for different elements are provided. Unless otherwise noted, such materials are given by way of example only and embodiments are not limited solely to the specific examples given. Similarly, unless otherwise noted, all dimensions and process parameters are given by way of example and embodiments are not limited solely to the specific dimensions or ranges given.

The descriptions of the various embodiments of the present invention have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A semiconductor structure, comprising:
a first set of transistors in a first level, the first set of transistors having a first gate pitch and a first cell height; and
a second set of transistors in a second level, the second set of transistors having a second gate pitch and a second cell height;
wherein the second level is vertically stacked over the first level;
wherein the first gate pitch is different than the second gate pitch; and
wherein the first cell height is different than the second cell height.

2. The semiconductor structure of claim 1, wherein the first gate pitch is greater than the second gate pitch.

3. The semiconductor structure of claim 1, wherein the first cell height is greater than the second cell height.

4. The semiconductor structure of claim 1, further comprising a middle-of-line contact between (i) a first source/drain region of one of the transistors in the first set of transistors in the first level and (ii) a second source/drain region of one of the transistors in the second set of transistors in the second level, wherein the first source/drain region at least partially overlaps the second source/drain region.

5. The semiconductor structure of claim 1, further comprising a middle-of-line contact between (i) a source/drain region of one of the transistors in the first set of transistors in the first level and (ii) a gate region of one of the transistors in the second set of transistors in the second level, wherein the source/drain region at least partially overlaps the gate region.

6. The semiconductor structure of claim 1, further comprising at least one via connecting a first interconnect on a first side of the semiconductor structure below the first level and a second interconnect on a second side of the semiconductor structure above the second level.

7. The semiconductor structure of claim 1, further comprising at least one interconnect on a first side of the semiconductor structure below the first level which connects to at least one transistor of the first set of transistors of the first level through one or more contacts below the first level.

8. The semiconductor structure of claim 1, further comprising one or more interconnects on a first side of the semiconductor structure below the first level, the one or more interconnects on the first side of the semiconductor structure comprising a power delivery network and signal wirings.

9. The semiconductor structure of claim 1, further comprising one or more interconnects on a second side of the semiconductor structure above the second level, the one or more interconnects on the second side of the semiconductor structure comprising a power delivery network and signal wirings.

10. A semiconductor structure comprising:
a first set of transistors in a first level, the first set of transistors having a first gate pitch and a first cell height;
a second set of transistors in a second level, the second set of transistors having a second gate pitch and a second cell height, wherein the second level is vertically stacked over the first level; and
a middle-of-line contact between a first region of one of the transistors in the first set of transistors in the first level and a second region of one of the transistors in the second set of transistors in the second level, the first region at least partially overlapping the second region.

11. The semiconductor structure of claim 10, wherein the first gate pitch is different than the second gate pitch.

12. The semiconductor structure of claim 11, wherein the first cell height is different than the second cell height.

13. The semiconductor structure of claim 10, wherein the first region comprises a first source/drain region of said one of the transistors in the first set of transistors and the second region comprises a second source/drain region of said one of the transistors in the second set of transistors.

14. The semiconductor structure of claim 10, wherein the first region comprises a source/drain region of said one of the transistors in the first set of transistors and the second region comprises a gate region of said one of the transistors in the second set of transistors.

15. The semiconductor structure of claim 10, further comprising at least one via connecting a first interconnect on a first side of the semiconductor structure below the first level and a second interconnect on a second side of the semiconductor structure above the second level.

16. An integrated circuit comprising:
a stacked transistor structure comprising:
a first set of transistors in a first level, the first set of transistors having a first gate pitch and a first cell height; and
a second set of transistors in a second level, the second set of transistors having a second gate pitch and a second cell height;
wherein the second level is vertically stacked over the first level;
wherein the first gate pitch is different than the second gate pitch; and
wherein the first cell height is different than the second cell height.

17. The integrated circuit of claim 16, wherein the first gate pitch is greater than the second gate pitch.

18. The integrated circuit of claim 16, wherein the first cell height is greater than the second cell height.

19. The integrated circuit of claim 16, further comprising a middle-of-line contact between (i) a first source/drain region of one of the transistors in the first set of transistors in the first level and (ii) a second source/drain region of one of the transistors in the second set of transistors in the second level, wherein the first source/drain region at least partially overlaps the second source/drain region.

20. The integrated circuit of claim 16, further comprising a middle-of-line contact between (i) a source/drain region of one of the transistors in the first set of transistors in the first level and (ii) a gate region of one of the transistors in the second set of transistors in the second level, wherein the source/drain region at least partially overlaps the gate region.
